(19) United States
(12) Patent Application Publication
(10) Pub. No.: US 2007/0129906 A1
(43) Pub. Date: Jun. 7, 2007

(54) Method and apparatus for maintaining an imaging device

(76) Inventors: Steven D. Stoecker, Fort Collins, CO (US); Timothy Louis Kohler, Palo Alto, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/292,467

(22) Filed: Dec. 2, 2005

(51) Int. Cl. G06F 19/00; G01R 31/00; G08B 21/00

(52) U.S. Cl. 702/108; 702/57; 324/500; 340/635

(57) ABSTRACT

An exemplary operation for maintaining an imaging device includes obtaining an identification of the imaging device connected to a kiosk, testing the imaging device at the kiosk with at least one test that is selected for the imaging device based on the identification, and transmitting information about the imaging device from the kiosk to at least one remote server.

### BACKGROUND

Modern imaging devices such as digital or film cameras and video cameras are largely automated, making them very simple to use. For example, imaging device settings such as shutter speed, exposure time, white balance, focus settings, etc, may be controlled electronically in the imaging device without the need for user intervention. The automatic settings may be determined based on a number of factors, including environmental conditions, user-selected settings, the characteristics of the components in the imaging device, preferences or algorithms established by the manufacturer, etc. For example, shutter speed, exposure time, gain and flash settings may be adjusted according to the ambient light level. In digital imaging devices in particular, image data is extensively processed after being captured by an image sensor to adjust image characteristics such as color, contrast, sharpness, white balance, gain, etc., according to algorithms established by the manufacturer. Even user-selected settings are typically applied in modern imaging devices under electronic control by a microprocessor or microcontroller.

The extensive automation and electronic control in modern imaging devices adds a layer of complexity to the calibration and maintenance processes, while allowing for adjustments that may not have been possible in purely mechanical imaging devices. The manufacturer typically calibrates a large number of parameters in an image device, such as the required gain for a particular image sensor, lens positions for focusing at various subject distances, etc. Some of these parameters may vary from imaging device to imaging device in the same product line. For example, the sensitivity of image sensors may vary from part to part, requiring calibration at the time of manufacture for uniformity.

Imaging device characteristics may also change over time, such as an image sensor becoming less sensitive with age, a flash becoming less intense, or a lens focus drive mechanism becoming less responsive. A manufacturer may also provide firmware upgrades for an imaging device to correct faults in a user interface or control system or to improve image quality.

To maintain an imaging device, including testing, calibrating, or upgrading, a user has typically had to deliver the imaging device to a repair facility for manual testing and repair or adjustment. This inconvenience causes consumer dissatisfaction, and does not greatly aid the manufacturer in supporting the product line and enhancing the consumer's experience with the imaging device. The use of independent repair facilities also makes it difficult for the manufacturer to assert quality control over the maintenance of imaging devices and to obtain information that would improve new imaging devices.

### BRIEF DESCRIPTION OF THE DRAWINGS

Illustrative embodiments are shown in the accompanying drawings as described below.

FIG. 1 is a block diagram illustrating an exemplary imaging device maintenance system.

FIG. 2 is a block diagram illustrating an exemplary kiosk that may be used in an imaging device maintenance system.

FIG. 3 is a flow chart illustrating an exemplary operation for maintaining an imaging device.

FIG. 4 is a flow chart illustrating another exemplary operation for maintaining an imaging device.

FIG. 5 is a flow chart illustrating another exemplary operation for maintaining an imaging device.

### DESCRIPTION

The drawings and description, in general, disclose a method and apparatus for maintaining an imaging device. A kiosk is provided enabling a user to test and configure an imaging device and to perform firmware upgrades in the imaging device in a convenient and rapid manner. The term “kiosk” is used herein to refer to a structure including computer equipment and a user interface to which a camera may be connected and maintained by a user or a store clerk. An exemplary kiosk may be configured in any desired manner, such as with a touch screen or keyboard or both, an audio system, a video display system, credit card or other payment processing system, compact disc (CD) burner, printer, etc, as will be described in more detail below. A network of kiosks may be provided to enable users to maintain their imaging devices, such as in retail stores or other public places. The kiosk may be operated directly by a user or by others, such as a store clerk or a repair facility employee.

Imaging devices that may be maintained by the method and apparatus disclosed herein include any device for capturing an image, such as a digital or film camera, a mobile phone or personal digital assistant that includes a camera, or a video camera of any type. The configuration of the imaging device will determine the method of connecting the imaging device to the kiosk. For example, a digital camera may include an electronic input/output (I/O) port that may be directly connected to the kiosk, either wired (e.g., cable) or wirelessly (e.g., radio frequency (RF) or infrared (IR)), allowing firmware upgrades, camera settings and image capture control commands to be transferred to the digital camera, and image data to be retrieved from the digital camera. An electronically controlled film camera may also include an I/O port that may be directly connect to the kiosk for transferring firmware, camera settings and test data, although image data may not be available for retrieval by the kiosk. Other imaging devices may not include an I/O port (whether wired or wireless), but may provide some type of removable storage such as solid state storage media, magnetic discs or tapes, or optical discs that may be removed from the imaging device and inserted into the kiosk for access. Still other imaging devices may provide no means for communicating with the kiosk, such as a purely mechanical imaging device. In this case, the user provides the connection between the imaging device and the kiosk by operating the imaging device according to instructions provided by the kiosk. For example, the kiosk may provide tests that require a user to manually operate the imaging device and to visually check the test results in developed and printed images. In one exemplary test, the kiosk may provide color test charts to be imaged or exposure length tests in which lights are briefly illuminated in varying locations in the field of view, so that the exposure duration can be calculated by performing an exposure with a fixed duration and counting the number of lights captured in the resulting image.

In one exemplary embodiment, the method and apparatus for maintaining an imaging device may comprise a kiosk having a testing system of the type shown and described in U.S. patent application Ser. No. 11/054,210, filed Feb. 8, 2005, entitled “Imaging Device Analysis Systems and Imaging Device Analysis Methods”, which is incorporated herein by reference for all that it discloses. Alternatively, the testing system may comprise any suitable system for testing any feature of an imaging device, whether the testing system is now known or is developed in the future. The imaging device may be fully or partially controlled by the kiosk during the test, or may be controlled by the user. The results may be fully or partially evaluated by the kiosk, or may be evaluated by the user. The tests performed by the kiosk may be directed to any feature of the imaging device, such as the imaging performance, the user interface, the storage system, the lens system, etc.

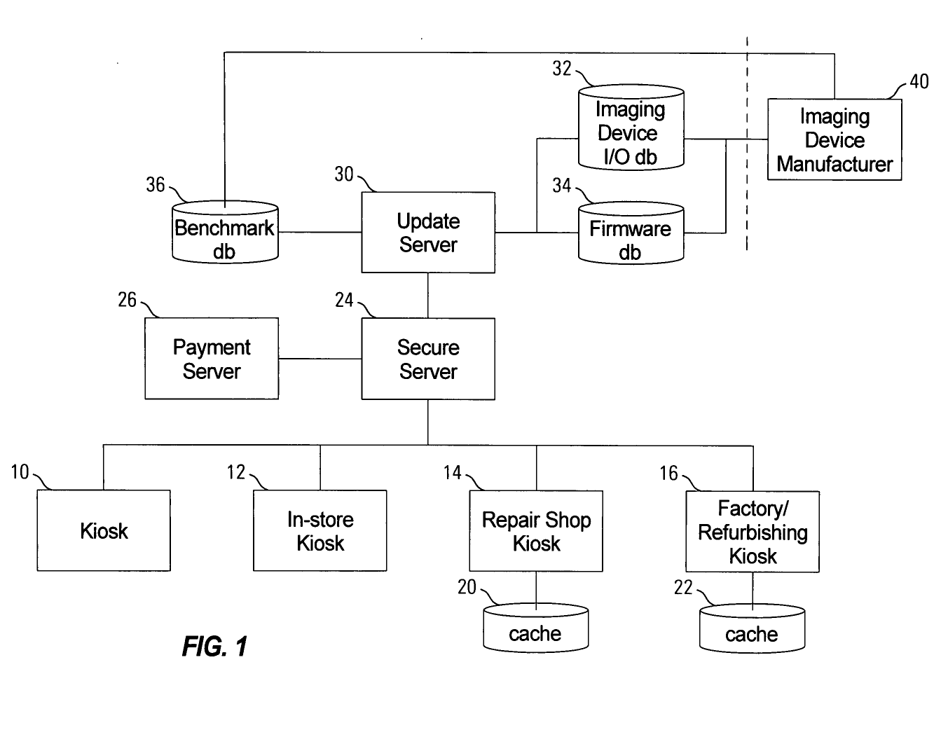

Referring now to FIG. 1, an exemplary embodiment of the method and apparatus for maintaining an imaging device will be described in more detail. One or more kiosks may be provided for maintaining one or more types of imaging devices. Kiosks 10 may be placed in public locations such as shopping malls and in-store kiosks 12 may be placed in retail stores to be operated by customers or clerks. Kiosks 14 may be placed in repair shops to facilitate testing and firmware upgrades by repair technicians, and kiosks 16 may also be placed in factory maintenance or refurbishing facilities. Local caches 20 and 22 may be provided in kiosks 14 and 16 to store firmware upgrades, connectivity information regarding imaging device interfaces, tests and test results, etc, to improve performance of heavily used kiosks or to reduce network bandwidth requirements during peak times. The kiosks 10-16 may be connected to a network such as the Internet through one or more secure servers 24, allowing firmware upgrades, tests and test results, payment information, etc to be transferred between the kiosks 10-16 and other devices on the network. A payment server 26 may be provided to process payment for services used at the kiosk (e.g., 12). Payment may be processed in any desired manner, such as using credit cards. The secure server 24 may receive firmware upgrades, connectivity information, and expected test results from an update server 30.

An imaging device I/O database 32 may be provided containing connectivity information for one or more types of imaging devices. The imaging device I/O database 32 provides information needed to connect imaging devices to a kiosk (e.g., 12), such as communication protocols and available commands. The imaging device I/O database 32 may also provide information instructing the user on how an imaging device should be connected to the kiosk (e.g., 12), such as which of a number of available connectors should be used, or how to transfer a removable storage medium between an imaging device and the kiosk (e.g., 12). The imaging device I/O database 32 may also provide information regarding what types of tests are available for a particular imaging device. The kiosk (e.g., 12) retrieves connectivity information from the imaging device I/O database 32 through the secure server 24 and update server 30 and may store the information locally in a cache (e.g., 20) if desired.

A firmware database 34 may also be provided containing various firmware releases for one or more types of imaging devices. The firmware database 34 may provide procedures for automatically installing firmware in a particular imaging device, or for providing instructions enabling a user to install the firmware. For example, firmware may be written to removable media or transportable storage device such as a compact disc, solid state memory, etc, by the kiosk (e.g., 12), enabling the user to keep a copy of the firmware and to install the firmware to an imaging device at home. The firmware and associated procedures or instructions may be communicated to kiosks (e.g., 14) through the update server 30 and secure server 24, and may be stored locally in a cache (e.g., 20) if desired.

A benchmark database 36 may be provided containing expected test results for various tests in a number of types of imaging devices. The benchmark data may be provided by imaging device manufacturers or may be gathered from previously tested imaging devices or from any other suitable source. The benchmark data may be communicated to kiosks (e.g., 14) through the update server 30 and secure server 24, and may be stored locally in a cache (e.g., 20) if desired. Actual test results may be compared in the kiosk (e.g., 14) with the expected test results from the benchmark database 36, and an indication of the imaging device's performance may be provided to the user. Actual test results may also be stored in the benchmark database 36 or in another repository and provided or sold to imaging device manufacturers or other third parties. Other information may be provided to imaging device manufacturers by the kiosk along with test results, such as firmware upgrade information, imaging device identification, kiosk location, etc. The kiosk may also make adjustments to settings in imaging devices to improve performance based on actual test results according to information from the imaging device I/O database 32, firmware database 34, benchmark database 36 or other sources. For example, if a test indicates that an imaging device is using incorrect exposure lengths, the exposure settings in the imaging device may be recalibrated by the kiosk.

One or more imaging device manufacturers (e.g., 40) may be connected to the databases 32, 34 and 36 or the update server 30 to provide connectivity information, firmware, benchmark data, etc, to the kiosks. Software in the kiosk may also be directly updated by the imaging device manufacturer (e.g., 40) if desired through the update server 30 and other devices on the network. Firmware, connectivity information and benchmark data may also be pushed to kiosks from servers at scheduled times for local storage in a cache (e.g., 20).

In alternative embodiments, the network for supporting the kiosks may comprise any desired configuration of network devices (e.g., servers) and network connections. The network may include a direct connection to imaging device manufacturers or may be connected to a third party that gathers information about imaging devices. Kiosks may be owned and operated by one or more imaging device manufacturers, or by individual retail stores, or any other organizations. Information may be stored in one or more databases or in any other suitable repository.

Because the kiosks 10-16 are connected to a network, the owner of a system (optionally including the secure server 24, payment server 26, update server 30, imaging device I/O database 32, firmware database 34 and benchmark database 36), may gather information about the use of the kiosks, identifying which types of imaging devices are being used, maintained and upgraded, and what faults are being detected in the imaging devices.

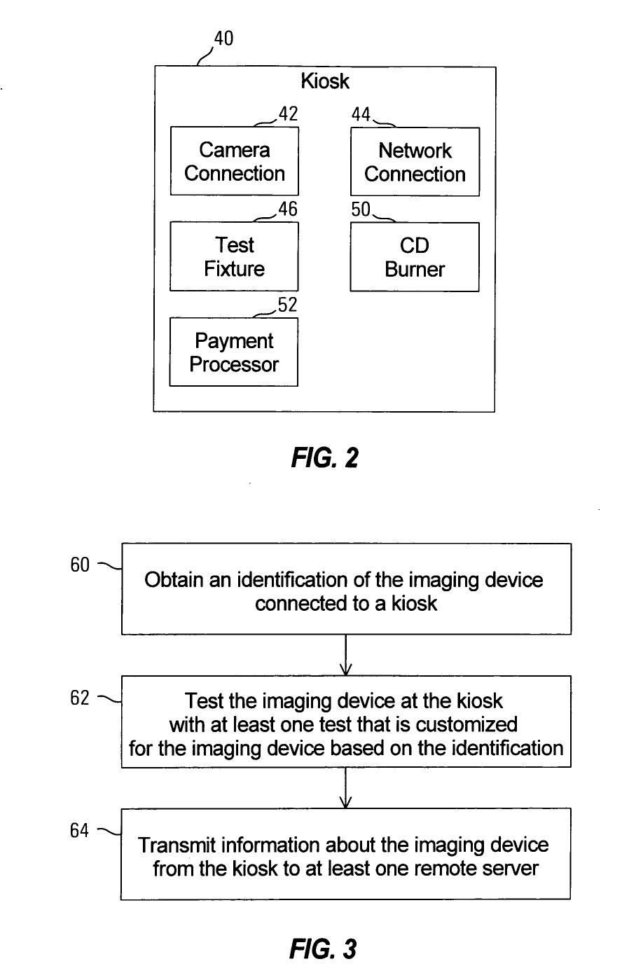

Referring now to FIG. 2, an exemplary kiosk 40 will be described in more detail. One or more imaging device connections 42 may be provided, including wired connections such as Universal Serial Bus (USB) cables, etc, wireless connections such as infrared (IR), etc, or removable media cards, tapes or discs that may be manually transferred between imaging devices and a kiosk. A network connection 44 is provided, connecting the kiosk 40 to network servers containing connectivity, test, and other information. One or more test fixtures 46 are provided, enabling an imaging device to be tested at the kiosk. The test fixture 46 may control the imaging device or may instruct the user to perform various operations on the imaging device. The test fixture 46 may also display various test patterns to be imaged, and may perform any other function useful for testing an imaging device. Note that the imaging device connection 42 and test fixture 46 may share a common connection point to the imaging device. A compact disc burner or writer 50, or other means for writing to removable media, may also be provided to store firmware, test results, software such as image editing software, etc, for a user. The kiosk 40 may also contain a payment processor 52 such as a credit card reader, internet browser interface, entry device for a code or barcode purchased from a clerk, bill and coin input, or any other form of payment acceptance. Alternatively, payment may be made to a cashier or store clerk for fee-based services provided at the kiosk. Because kiosks are well known in the art and may be configured as desired, other elements that may be included in the kiosk 40, such as a touch screen and keyboard, will not be described in more detail herein.

An exemplary operation for maintaining an imaging device is summarized in the flow chart of FIG. 3. The operation includes obtaining 60 an identification of the imaging device connected to a kiosk, testing 62 the imaging device at the kiosk with at least one test that is customized for the imaging device based on the identification, and transmitting 64 information about the imaging device from the kiosk to at least one remote server. The imaging device identification may include information such as model and/or serial number, manufacturer identification, information about peripherals such as memory card manufacturer and capacity, etc. This information may be provided to an imaging device I/O database to retrieve connectivity information for the imaging device, enabling the kiosk to communicate with the imaging device. The imaging device identification may be electronically detected or read from the imaging device by the kiosk, or may be entered by the user.

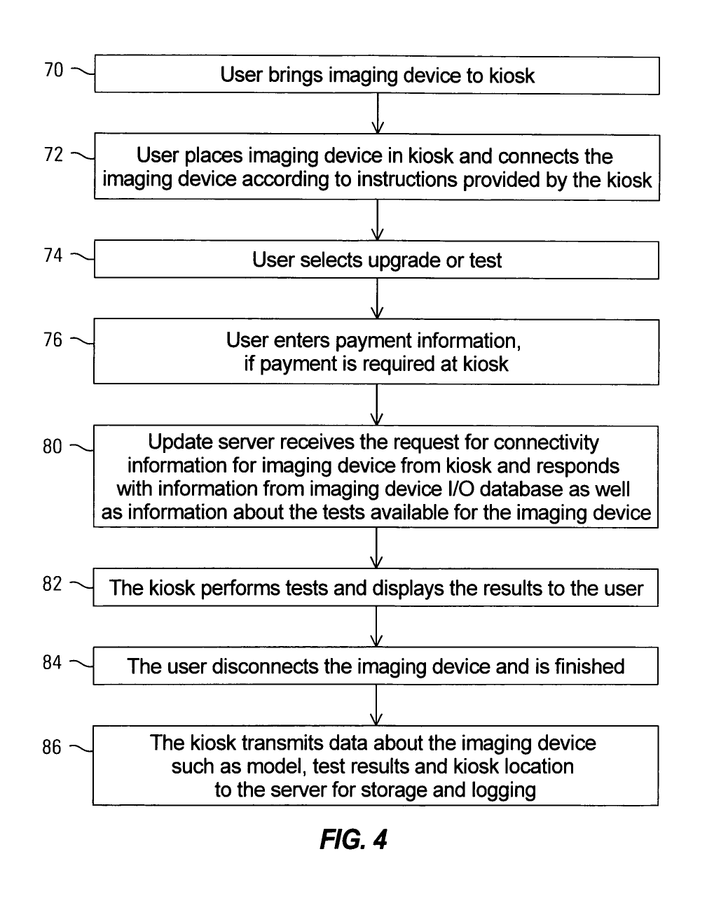

An exemplary operation for testing an imaging device at a kiosk is described in more detail in the flow chart of FIG. 4. The user brings 70 an imaging device to a kiosk, places 72 the imaging device in the kiosk and connects the imaging device according to instructions provided by the kiosk. The user selects 74 between imaging device upgrade or test, in this case selecting test. The user enters 76 payment information, if payment is required at the kiosk. An update server receives 80 a request for connectivity information for the imaging device from the kiosk and responds with information from an imaging device I/O database, as well as information about the tests available for the imaging device. The kiosk performs 82 the tests and displays the results to the user, optionally calibrating or adjusting the imaging device if needed according to the test results. The user disconnects 84 the imaging device and is finished. The kiosk transmits 86 data about the imaging device such as the model, test results and kiosk location to the server for storage and logging, and optional sale to third parties.

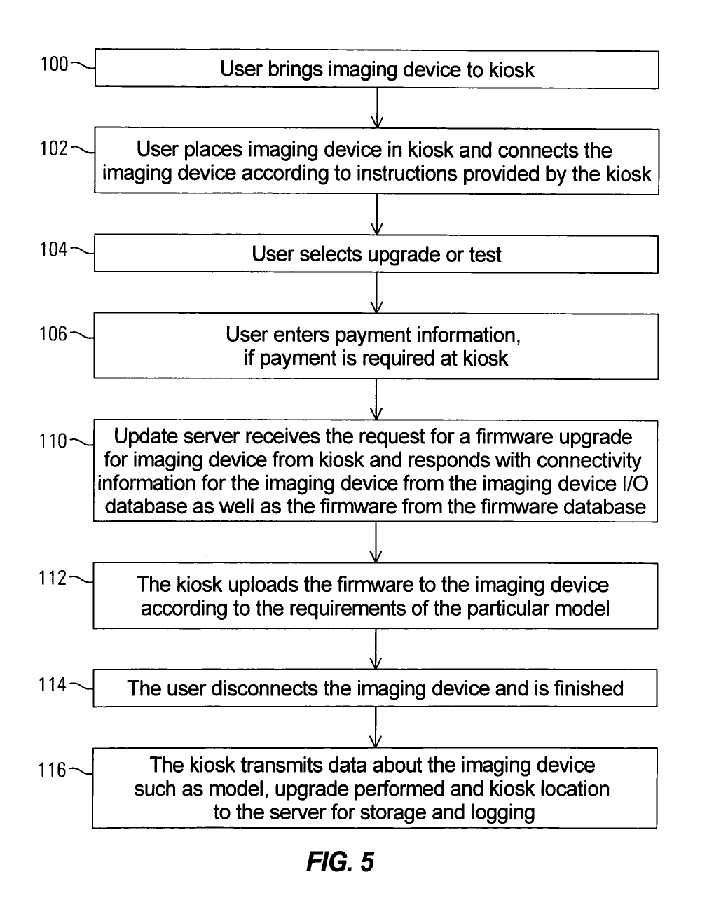

An exemplary operation for upgrading an imaging device at a kiosk is described in the flow chart of FIG. 5. The user brings 100 an imaging device to a kiosk, places 102 the imaging device in the kiosk and connects the imaging device according to instructions provided by the kiosk. The user selects 104 between imaging device upgrade or test, in this case selecting upgrade. The user enters 106 payment information, if payment is required at the kiosk. An update server receives 110 the request for a firmware upgrade for the imaging device from the kiosk and responds with connectivity information for the imaging device from an imaging device I/O database as well as the firmware from a firmware database. The kiosk upload 112 the firmware to the imaging device according to the requirements of the particular model while displaying status information to the user, or alternatively, stores the firmware on a disk or other media for the user to install later. The user disconnects 114 the imaging device and is finished. The kiosk transmits 116 data about the imaging device such as the model, upgrade performed and kiosk location to the server for storage and logging, and optional sale to third parties.

The method and apparatus for maintaining an imaging device described herein provides significant benefits for imaging device users as well as imaging device manufacturers, firmware providers, and others. The kiosks provided in the system enable users to conveniently test and calibrate or adjust their imaging devices and upgrade firmware. The method and apparatus also gathers information that can be provided or sold to manufacturers or other third parties to aid in development, maintenance and marketing efforts. For example, imaging device maintenance kiosks may gather information such as how imaging device performance degrades over time, how long particular models remain in use, and how widely new firmware upgrades are distributed. Other useful functions may also be provided at the kiosks, such as traditional image manipulation and printing. Fees for the use of imaging device maintenance kiosks may be collected in a number of ways, such as collecting payment directly from a user at the kiosk or by a cashier, or retail stores may purchase or rent a kiosk and provide free access as a service to customers to increase their business.

While illustrative embodiments have been described in detail herein, it is to be understood that the concepts disclosed herein may be otherwise variously embodied and employed, and that the appended claims are intended to be construed to include such variations, except as limited by the prior art.

What is claimed is:

1. A method of maintaining an imaging device, the method comprising:
obtaining an identification of said imaging device connected to a kiosk;
testing said imaging device at said kiosk with at least one test that is selected for said imaging device based on said identification; and
transmitting information about said imaging device from said kiosk to at least one remote server.

2. The method of claim 1, further comprising downloading connectivity information about said imaging device from a connectivity database and establishing communication between said kiosk and said imaging device based on said connectivity information.

3. The method of claim 1, further comprising downloading expected performance information from a benchmark database to said kiosk, and comparing a result of said at least one test with said expected performance information in said kiosk.

4. The method of claim 1, further comprising automatically configuring said imaging device at said kiosk based on a result of said at least one test.

5. The method of claim 1, further comprising downloading firmware from a firmware database to said imaging device in said kiosk.

6. The method of claim 1, further comprising said kiosk storing at least one member selected from the group consisting of firmware, connectivity information and benchmark data in a local cache.

7. The method of claim 1, further comprising downloading firmware from a firmware database to said kiosk and storing said firmware in a transportable storage device.

8. The method of claim 1, further comprising processing payment in said kiosk for said testing.

9. The method of claim 1, wherein said information comprises at least one member selected from the group consisting of imaging device identification, results of said at least one test, location of said kiosk, and firmware upgrade performed to said imaging device at said kiosk.

10. The method of claim 9, further comprising selling said information.

11. The method of claim 1, further comprising obtaining customer information at said kiosk and transmitting said customer information to said at least one remote server.

12. The method of claim 1, wherein said obtaining said identification comprises at least one member selected from the group consisting of electronically reading said identification from said imaging device and accepting said identification as user input.

13. The method of claim 1, further comprising receiving data at said kiosk pushed from said at least one remote server, said data comprising at least one member selected from the group consisting of imaging device connectivity information, imaging device firmware, and imaging device expected performance data.

14. The method of claim 1, wherein said kiosk comprises a self-serve kiosk for direct consumer use.

15. The method of claim 1, wherein said kiosk comprises a clerk-operated kiosk.

16. An imaging device maintenance system, comprising:
a network server;
a connectivity database comprising imaging device connectivity information, said connectivity database being accessible by said network server; and
at least one kiosk, said kiosk comprising:
an imaging device interface for communicating with an imaging device according to information in said connectivity database;
a network connection connected to said network server;
a user interface; and
a test fixture, wherein said imaging device may be tested at said kiosk and information about said imaging device may be transmitted to said network server.

17. The imaging device maintenance system of claim 16, further comprising a firmware database comprising imaging device firmware, said firmware database being accessible by said network server, wherein said user interface is adapted to enable a user to download firmware for said imaging device from said firmware database to said kiosk and to install said firmware in said imaging device.

18. The imaging device maintenance system of claim 16, further comprising a payment server, said kiosk further comprising a payment processor that is connectable to said payment server through said network connection.

19. The imaging device maintenance system of claim 16, further comprising a benchmark database comprising expected performance information for at least one type of imaging device, said benchmark database being accessible by said network server, said kiosk being adapted to compare test data obtained by said test fixture with said expected performance information from said benchmark database.

20. The imaging device maintenance system of claim 16, wherein said kiosk comprises at least one member selected from the group consisting of a self-serve kiosk for direct consumer use and a clerk-operated kiosk.

21. An apparatus for maintaining an imaging device, comprising:
means for identifying said imaging device in a kiosk;
means for testing said imaging device at said kiosk; and
means for providing information about said imaging device to a manufacturer of said imaging device.
